(19) United States
(12) Patent Application Publication
(10) Pub. No.: US 2017/0069836 A1
(43) Pub. Date: Mar. 9, 2017

(54) METHOD OF MANUFACTURING SEMICONDUCTOR DEVICE AND APPARATUS FOR MANUFACTURING THE SAME

(71) Applicant: KABUSHIKI KAISHA TOSHIBA, Tokyo (JP)

(72) Inventor: Kazuhiro TOMIOKA, Seoul (KR)

(73) Assignee: KABUSHIKI KAISHA TOSHIBA, Tokyo (JP)

(21) Appl. No.: 15/067,098

(22) Filed: Mar. 10, 2016

Related U.S. Application Data
(60) Provisional application No. 62/215,723, filed on Sep. 8, 2015.

(51) Int. Cl. H01L 43/12; H01J 37/20; H01J 37/305; H01L 43/08; H01L 43/02

(52) U.S. Cl. CPC H01L 43/12; H01L 43/08; H01L 43/02; H01J 37/3056; H01J 37/20; H01J 2237/3174; H01J 2237/2007; H01J 2237/063; H01J 2237/08

(57) ABSTRACT

According to one embodiment, a method of manufacturing a semiconductor device includes forming a mask on a film provided on a substrate, selectively etching the film by applying an ion beam of an inert gas to the film after the forming of the mask, and applying an electron beam to the film after the etching.

### CROSS-REFERENCE TO RELATED APPLICATIONS

This application claims the benefit of U.S. Provisional Application No. 62/215,723, filed Sep. 8, 2015, the entire contents of which are incorporated herein by reference.

### FIELD

Embodiments described herein relate generally to a method of manufacturing a semiconductor device and an apparatus for manufacturing the same.

### BACKGROUND

Recently, large-capacity magnetoresistive random access memories (MRAMs) using magnetic tunnel junction (MTJ) elements have been gaining attention and raising expectations. The MTJ element comprises two magnetic layers sandwiching a tunnel barrier layer: a magnetization fixed layer (reference layer) having a fixed direction of magnetization and a magnetization free layer (storage layer) having an easily reversible direction of magnetization.

To form the MTJ element, the laminated film of the magnetic layers and the barrier layer is selectively etched by IBE using an ion beam of an inert gas.

### BRIEF DESCRIPTION OF THE DRAWINGS

FIG. 1 is a schematic diagram showing an apparatus for manufacturing a semiconductor device of the first embodiment.

FIGS. 2A to 2C are schematic diagrams showing the manufacturing procedure of the semiconductor device of the first embodiment.

FIG. 3 is a diagram showing the Ar profiles of respective layers obtained after an IBE process.

FIGS. 4A and 4B are explanatory diagrams on the technical effect of the first embodiment showing a change in the amount of Ar attached.

FIG. 5 is a schematic diagram showing an apparatus for manufacturing a semiconductor device of the second embodiment.

### DETAILED DESCRIPTION

In general, according to one embodiment, a method of manufacturing a semiconductor device comprises: forming a mask on a film provided on a substrate; selectively etching the film by applying an ion beam of an inert gas to the film after the forming of the mask, and applying an electron beam to the film after the etching.

Apparatuses for manufacturing semiconductor devices and methods of manufacturing the same will be described below with reference to the accompanying drawings.

### First Embodiment

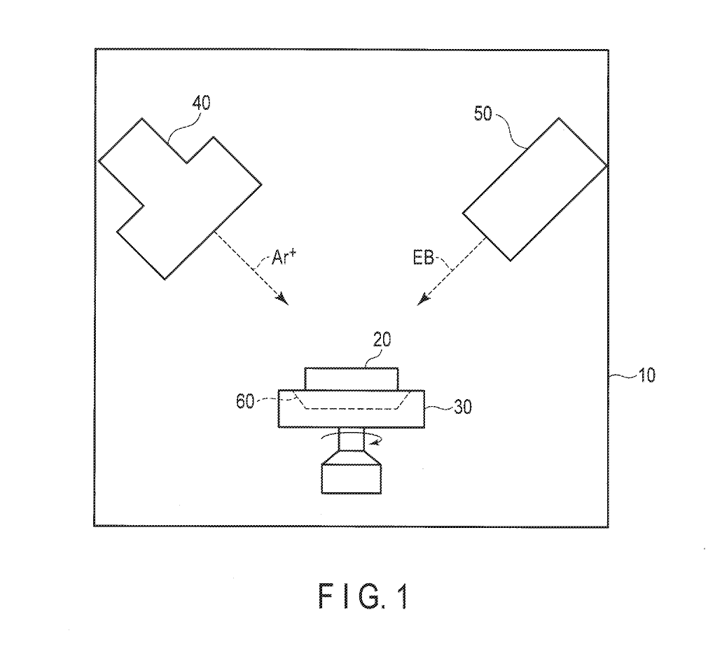

FIG. 1 is a schematic diagram showing an apparatus for manufacturing a semiconductor device of the first embodiment.

A vacuum chamber 10 accommodates a stage 30 on which a to-be-processed substrate 20 is mounted. The stage 30 is configured to be rotated by a motor or the like.

The chamber 10 is provided with an ion source 40 configured to produce an ion beam of Ar. The ion source 40 may be an ion source which uses microwave discharge or an ion source which ionizes a target by using the energy of a laser beam. Further, the ion source 40 is configured to apply an or beam obliquely to the surface of the to-be-processed substrate 20.

The chamber 10 is further provided with an electron source 50 configured to produce an electron beam. The electron source 50 produces an electron beam by an electron gun and draws the electron beam out by an acceleration electrode. The electron beam from the electron source 50 is applied obliquely to the surface of the to-be-processed substrate 20.

Further, a heater (heating mechanism) 60 configured to heat the to-be-processed substrate 20 is buried in the surface portion of the stage 30.

Note that, although the to-be-processed substrate 20 is provided horizontally in FIG. 1, it is also possible to tilt the stage 30, for example, 45 degrees relative to the horizontal, direction and hold the to-be-processed substrate in a tilted manner. In that case, it suffices that the ion beam and the electron beam are applied in the horizontal direction.

Next, a method of manufacturing a semiconductor device using the apparatus of FIG. 1, more specifically, a method of processing a laminated film for an MTJ element will be described.

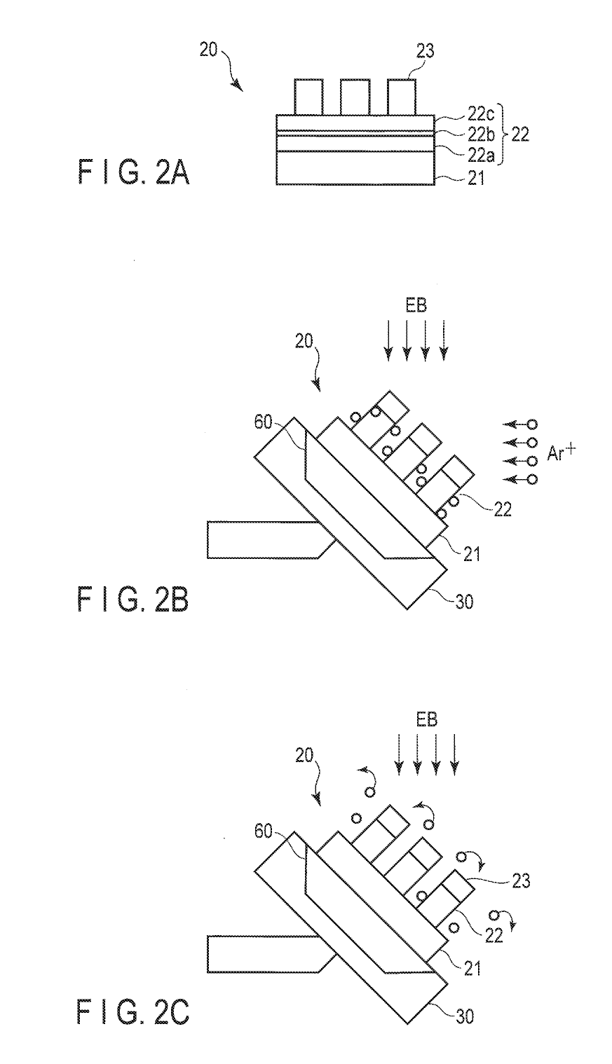

First, as shown in FIG. 2A, on the to-be-processed substrate 20 comprising a substrate 21 and a to-be-processed film 22 formed on the substrate 21, a mask 23 of a desired pattern is formed. The to-be-processed film 22 constitutes, for example, an MTJ element and has a stacked layer structure in which a nonmagnetic barrier layer 22b is sandwiched between a magnetic storage layer 22a and a magnetic reference layer 22c. The mask 23 can be formed of a conductive material such as Ta, W or the like or an insulating material of SiN or the like.

Then, the to-be-processed substrate 20 is carried into the chamber 10 of FIG. 1 and held on the stage 30. Subsequently, as shown in FIG. 2B, an ion beam is applied from the ion source 40 to the to-be-processed substrate 20 while the stage 30 is rotated. That is, the to-be-processed substrate 20 is etched by being irradiated with an ion beam (IBE). At this time, to prevent a charge-up phenomenon of the to-be-processed substrate 20, an electron beam is also applied from the electron source 50 to the to-be-processed substrate 20.

The ion source 40 is configured to produce an ion beam of, for example, Ar (Ar⁺) and has an acceleration voltage of, for example, 400-500 eV. The ion beam from the ion source 40 is applied obliquely to the surface of the to-be-processed substrate 20. Here, since the stage 30 is rotated, the ion beam is evenly applied to the to-be-processed substrate 20.

The electron source 50 performs a function of preventing the charge-up of the to-be-processed substrate 20 caused by being irradiated with an ion beam, and does not require significantly high energy. For example, energy of less than or equal to 100 eV is sufficient to perform the function.

By the above-described ion beam irradiation, the to-be-processed film 22 is selectively etched. In such ion beam etching as that of present embodiment, an etching speed is high, and thus the to-be-processed film 22 is etched almost vertically. At this time, it is recognized that Ar is attached to the etched sidewall surfaces.

After the ion beam irradiation is stopped, as shown in FIG. 2C, the to-be-processed substrate 20 is heated by the heater 60 to, for example, 500° C. and is also subjected to an electron beam from the electron source 50 at the same time. At this time, since the stage 30 is rotated, the electron beam is evenly applied to the to-be-processed substrate 20. Here, the energy of the electron beam is 100 eV, and the irradiation time is 1 minute.

By the above-described electron beam irradiation, it is possible to remove Ar attached to the etched sidewalls of the to-be-processed film 22. This removal of Ar attached thereto has a great effect especially on the to-be-processed film 22 which comprises magnetic layers as an MTJ element does.

Here, although the precise mechanism of Ar attachment to the etched sidewall surfaces in the ion beam etching is not known, the inventors have obtained the following findings.

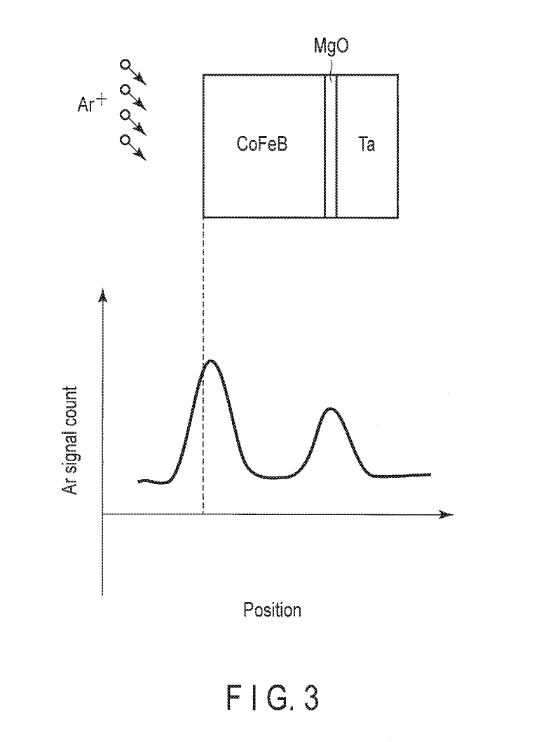

FIG. 3 is a diagram showing the amount of Ar attached to the to-be-processed film after the Ar ion beam is applied to the to-be-processed film. After a solid film of CoFeB/MgO/Ta was formed, and an Ar ion beam was applied obliquely to the solid film. Then, a SIMS signal for Ar was measured. As a result, a large amount of Ar was found in the end portion of CoFeB and in the portion of MgO.

Further, although the precise mechanism of removal of attached Ar in the electron beam irradiation is not known, the inventors have obtained the following findings.

It is known that components attached to a solid surface are removed when the solid surface is irradiated with electrons (Surface Science Society of Japan [1992], Journal of the Surface Science Society of Japan, 13(5), 244-248). For example, it is possible to remove Ar by applying an electron beam having energy of 20 eV or more. In the present embodiment, the electron beam (of 100 eV) is applied after the ion beam etching, and therefore Ar attached to the etched sidewall surfaces is similarly removed.

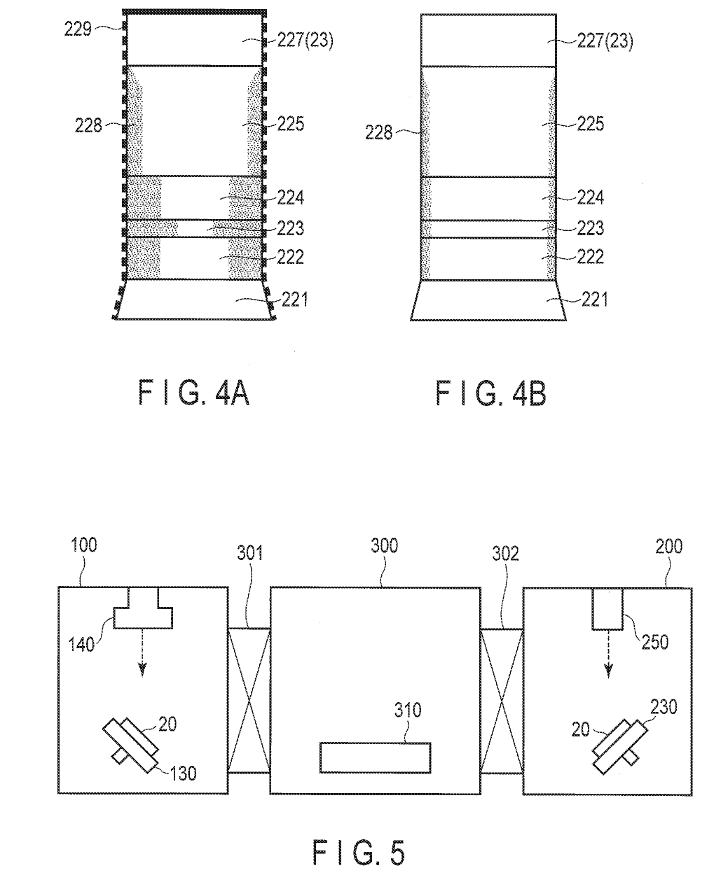

FIGS. 4A and 4B are schematic diagrams showing a change in the amount of Ar attached in the processing of the MTJ element. FIG. 4A shows the Ar distribution obtained after ion beam etching, while FIG. 4B shows the Ar distribution obtained after electron beam irradiation. The portions denoted by reference numbers 221, 222, 223, 224, 225 and 227 are an underlayer, a storage layer, a barrier layer, a reference layer, a shift-adjustment layer (shift cancelling layer) and a hard mask, respectively.

Here, for the storage layer 222, CoFeB or FeB can be used. For the tunnel barrier layer 223, MoO can be used. For the reference layer 224, CoPt, CoNi or CoPd can be used. For the shift-adjustment layer 225, CoPt, CoNi, or CdPd can be used.

As shown in FIG. 4A, in the ion beam etching of the to-be-processed film (225-221) using the hard mask 227, Ar is attached to the side surfaces of the to-be-processed film. When the component of an inert gas such as Ar is attached to the side surfaces of the MTJ element in this way, this may cause degradation in the characteristics of the MTJ element.

Here, since a heavy element is used for the mask, Ar only penetrates into a relatively shallow depth. On the other hand, Ar penetrates into a relatively deep depth in the case of a layer formed of a light element. For example, when the shift-adjustment layer 225 comprises an element such as Pt which is heavier as compared to the constituting elements of the storage layer 222 or the reference layers 224 such as Fe, Co and B, the shift-adjustment layer 225 allows Ar to penetrate into a shallower depth as compared to the storage layer 222 or the reference layer 224. Further, when the barrier layer 223 comprises an element such as MgO relatively lighter as compared to the constituting elements of the storage layer or the reference layer, the barrier layer 223 allows Ar to penetrate into a deeper depth. Note that reference number 228 indicates Ar penetrating into the to-be-processed film and that reference number 229 indicates Ar attached to the surfaces.

When the sample in this state is irradiated with an electron beam, Ar attached to the side surfaces of the to-be-processed film is removed as shown in FIG. 4B. Here, the effect of Ar removal increases as the element becomes lighter. That is, since a large amount of Ar is removed especially from the storage layer 222, the barrier layer 223, the reference layer 224 of the MTJ element, the post-processing, namely, the electron beam irradiation is significantly beneficial to the MTJ element.

As described above, according to the present embodiment, the to-be-processed film 22 selectively etched by being irradiated with an Ar ion beam is then irradiated with an electron beam, and therefore Ar attached to the side surfaces of the to-be-processed film 22 can be reduced. Further, since the to-be-processed substrate 20 is heated while being irradiated with an electron beam, Ar can be removed more effectively. Consequently, it is possible to prevent degradation in the characteristics of the MTJ element caused by Ar attachment.

Further, in the present embodiment, since the Ar ion beam is applied obliquely to the to-be-processed film 22 while the to-be-processed substrate 20 is rotated, the to-be-processed film 22 can be evenly irradiated with the ion beam and thus can be processed accurately. Still further, in the etching process of the to-be-processed film 22, it is possible to apply an electron beam together with an ion beam and thereby prevent the charge-up of the to-be-processed film 22 associated with the ion beam irradiation in advance.

### Second Embodiment

FIG. 5 is a schematic diagram showing an apparatus for manufacturing a semiconductor device of the second embodiment. Note that the portions the same as those of FIG. 1 are denoted by the same reference numbers and descriptions thereof will be omitted.

The present embodiment is different from the first embodiment in that the ion beam irradiation and the electron beam irradiation are performed in different champers.

A first chamber 100 is the same as the chamber 10 of FIG. 1 except that the first chamber 100 does not comprise the heater 60 configured to heat the to-be-processed substrate 20 and the electron source 50. That is, the first chamber 100 accommodates a rotatable first stage 130 configured to held the to-be-processed substrate 20. Further, the first chamber 100 is provided with an ion source 140 configured to apply an ion beam to the to-be-processed substrate 20 on the stage 130.

Note that the ion beam from the ion source 140 is applied obliquely to the surface of the to-be-processed substrate 20 in a manner similar to that of the first embodiment.

A second chamber 200 accommodates a rotatable second stage 230 configured to hold the to-be-processed substrate 20. Further, the second chamber 200 is provided with an electron source 250 configured to apply an electron beam to the to-be-processed substrate 20. Still further, a heater 260 configured to heat the to-be-processed substrate 20 is provided on the stage 230 in a manner similar to that of the first embodiment.

Note that the electron beam is applied from the electron source 250 obliquely to the surface of the to-be-processed substrate 20 in a manner similar to that of the first embodiment.

Between the first and second chambers 100 and 200, a carrying chamber 300 is provided. The first chamber 100 and the carrying chamber 300 are connected to each other via a gate valve 301, and the second chamber 200 and the carrying chamber 300 are connected to each other via a gate valve 302. Further, the carrying chamber 300 is provided with a carrying mechanism 310 configured to carry the to-be-processed substrate 20 to and from the chambers 100 and 200. In this way, the to-be-processed substrate 20 can be carried from the first chamber 100 to the second chamber 200.

Note that the carrying chamber 300 may further connect to a chamber used for protective film formation, a chamber used for post-processing and the like not shown in the drawing.

In the present embodiment, after the to-be-processed substrate 20 is carried into the first chamber 100, an ion beam is applied from the ion source 140 to the to-be-processed substrate 20 and the to-be-processed film 22 is thereby selectively etched. Here, in a manner similar to that of the first embodiment, it is possible to further provide the chamber 100 with an electron source to perform electron beam irradiation for charge-up prevention.

After the to-be-processed film 22 is etched, the gate valve 301 is opened and then the to-be-processed substrate 20 is carried into the carrying chamber 300. After the gate valve 301 is closed, the gate valve 302 is opened and then the to-be-processed substrate 20 is carried into the second chamber 200.

In the second chamber 200, the to-be-processed substrate 20 is heated and the stage 230 is rotated at the same time. Then, the to-be-processed substrate 20 is irradiated with an electron beam from the electron source 250. In this way, Ar attached to the etched sidewall surfaces of the to-be-processed film 22 can be removed.

As described above, in the present embodiment, after the to-be-processed film 22 is etched by ion beam irradiation in the first chamber 100, Ar attached to the side surfaces of the to-be-processed substrate 20 can be removed in the second chamber 200. Therefore, an effect similar to that produced by the first embodiment can be achieved.

Further, since the first chamber 100 has a structure similar to those of existing ion beam irradiation apparatuses, the apparatus of the present embodiment can be realized simply by connecting the Ar removing second chamber 200 to an existing ion beam apparatus. Consequently, it is possible to reduce the cost of manufacturing the apparatus.

### Modification

Note that the present invention is not limited to each of the embodiments described above.

As the gas used for the ion beam etching, not only Ar but also various other inert gases such as He, Ne, Kr, Xe, Ra and the like can be used. Further, the conditions such as an acceleration voltage of the ion beam in the etching process, an acceleration voltage of the electron beam in the post-processing, a temperature for heating the to-be-processed substrate and the like described above are in no way restrictive and may be modified appropriately.

The structure of the to-be-processed film is not limited to that of FIG. 2A or those of FIGS. 4A and 4B and may be modified appropriately based on the specifications of an MTJ element. Further, the to-be-processed film is not necessarily limited to the stacked layer structure constituting an MTJ element and may be any structure which can be subjected to ion beam etching. That is, the present invention is not necessarily limited to the stacked layer structure for an MTJ element and may also be applied to various semiconductor materials as long as the materials can be subjected to ion beam etching.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming a mask or a film provided on a substrate;
selectively etching the film by applying an ion beam of an inert gas to the film after the forming of the mask; and
applying an electron beam to the film after the etching.

2. The method of claim 1, wherein
the film has a stacked layer structure in which a nonmagnetic layer is provided between magnetic layers.

3. The method of claim 2, wherein
the film constitutes an MTJ element includes a storage layer, a reference layer, and a tunnel barrier layer between the storage layer and the reference layer.

4. The method of claim 2, wherein
the ion beam is applied from an ion source to the film.

5. The method of claim 4, wherein
the ion beam is applied obliquely to a surface of the film while rotating the substrate.

6. The method of claim 1, wherein
the electron beam is applied from an electron source to the film.

7. The method of claim 6, wherein
the electron beam is applied to the film while heating the substrate.

8. The method of claim 6, wherein
the electron beam is applied obliquely to a surface of the film while rotating the substrate.

9. The method of claim 1, wherein
the inert gas is one of Ar, He, Ne, Kr, Xe and Ra.

10. The method of claim 1, wherein
the selectively etching the film includes applying the ion beam to process the film and applying an electron beam.

11. An apparatus for manufacturing a semiconductor device, comprising:
a chamber accommodating a stage for holding a substrate;
an ion source provided in the chamber and configured to apply an ion beam of an inert gas to the substrate;
an electron source provided in the chamber and configured to apply an electron beam to the substrate; and
a heating mechanism configured to heat the substrate.

12. The apparatus of claim 11, further comprising
a rotation mechanism configured to rotate the stage and wherein
the ion source applies the ion beam obliquely to a surface of the substrate, and the electron source applies the electron beam obliquely to the surface of the substrate.

13. The apparatus of claim 11, wherein
the substrate is irradiated with the ion beam and thereby processed, and
the substrate is irradiated with the electron beam while being heated, and an inert gas component attached to a surface of the substrate is thereby removed.

14. An apparatus for manufacturing a semiconductor device, comprising:
a first chamber accommodating a first stage for holding a substrate;
an ion source provided in the first chamber and configured to apply an ion beam of an inert gas to the substrate;
a second chamber accommodating a second stage for holding the substrate;
a first electron source provided in the second chamber and configured to apply an electron beam to the substrate; and
a carrying mechanism configured to carry the substrate from the first chamber to the second chamber.

15. The apparatus of claim 14, further comprising
a rotation mechanism configured to rotate the first stage and wherein
the ion source applies the on beam obliquely to a surface of the substrate.

16. The apparatus of claim 14, further comprising
a rotation mechanism configured to rotate the second stage and wherein
the electron source applies the electron beam obliquely to a surface of the substrate.

17. The apparatus of claim 14, further comprising
a second electron source provided in the first chamber and configured to apply an electron beam to the substrate.

18. The apparatus of claim 14, further comprising
a heating mechanism provided in the second chamber and configured to heat the substrate.
